(19) United States
(12) Patent Application Publication
(10) Pub. No.: US 2026/0198300 A1
(43) Pub. Date: Jul. 9, 2026

(54) INTERCONNECT STRUCTURE HAVING LAYERED AIR GAPS AND METHOD FOR MANUFACTURING THE SAME

(71) Applicant: TAIWAN SEMICONDUCTOR MANUFACTURING COMPANY, LTD., Hsinchu (TW)

(72) Inventors: Hsin-Ning HUNG, Hsinchu (TW); Zi Yi YANG, Hsinchu (TW); Ting-Ya LO, Hsinchu (TW); Hsin-Yen HUANG, Hsinchu (TW); Hsiao-Kang CHANG, Hsinchu (TW)

(73) Assignee: TAIWAN SEMICONDUCTOR MANUFACTURING COMPANY, LTD., Hsinchu (TW)

(21) Appl. No.: 19/011,073

(22) Filed: Jan. 6, 2025

(51) Int. Cl. H01L 21/768; H01L 23/528; H01L 23/532

(52) U.S. Cl. CPC H10W 20/46; H10W 20/072; H10W 20/075; H10W 20/435; H10W 20/47

(57) ABSTRACT

A method for manufacturing an interconnect structure includes: forming a first conductive line, a second conductive line, and a third conductive line on a base structure, the second conductive line being located between and spaced apart from the first conductive line and the third conductive line; forming a conductive via on the second conductive line opposite to the base structure; forming two lower air gaps each of which is located between the second conductive line and a respective one of the first conductive line and the third conductive line; forming a dielectric layer so that the conductive via is located in the dielectric layer; and forming two upper air gaps in the dielectric layer so that the two upper air gaps are located at two opposite sides of the conductive via.

### BACKGROUND

In integrated circuit design, resistive-capacitive delay (hereinafter RC delay) is a critical factor influencing circuit performance. As technology nodes advance and circuit dimensions shrink, the impact of parasitic capacitance becomes increasingly significant. Reducing parasitic capacitance is essential for enhancing circuit speed and lowering power consumption. Design engineers must employ advanced fabrication techniques and optimized layout strategies to minimize parasitic capacitance and improve RC delay performance. By implementing these measures, it is possible to meet high-performance requirements while reducing energy consumption, thereby driving integrated circuits toward greater efficiency and capabilities.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing an interconnect structure in accordance with some embodiments.

FIGS. 2 to 32 are schematic views illustrating intermediate stages of the method depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the terms “about” and “substantially” even if the terms “about” and “substantially” are not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the terms “about” and “substantially,” when used with a value, can capture variations of, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions and could be understood by those skilled in the art after reviewing the present disclosure.

As the scale of metal-oxide-semiconductor field-effect transistor (hereinafter MOSFET) becomes smaller and smaller, RC delay will play an increasing important role because it hinders the performance of integrated circuits for advanced technology nodes. Since RC delay is caused by parasitic effects, the reduction of parasitic capacitance between metal lines is necessary in the back end of line (hereinafter BEOL) process. In order to reduce the parasitic capacitance, in semiconductor manufacturing, a relative dielectric constant of a material, or capacitance of a material has to be lowered, and the capacitance of the material may be minimized when there are air gaps in the material. Generally, air gaps are formed by a reactive-ion etching technology (hereinafter RIE). Therefore, the reduction of the parasitic capacitance between metal lines can be achieved by engineering a metal RIE air-gap scheme to improve the performance of microelectronic devices. Specifically, an increase in the air/dielectric ratio within an RIE structure reduces the parasitic capacitance. However, the current metal RIE air-gap scheme is applied only to a trench part around metal lines, and a via part around metal vias that are connected to the metal lines, which has a circuit density lower than that of the trench part, is not formed with any air gaps. Therefore, the present disclosure is directed to methods for manufacturing an interconnect structure, in which air gaps are formed in both a via part and a trench part thereof to reduce parasitic capacitance, thereby achieving greater capacitance benefits and enhancing the functionality of microelectronic devices.

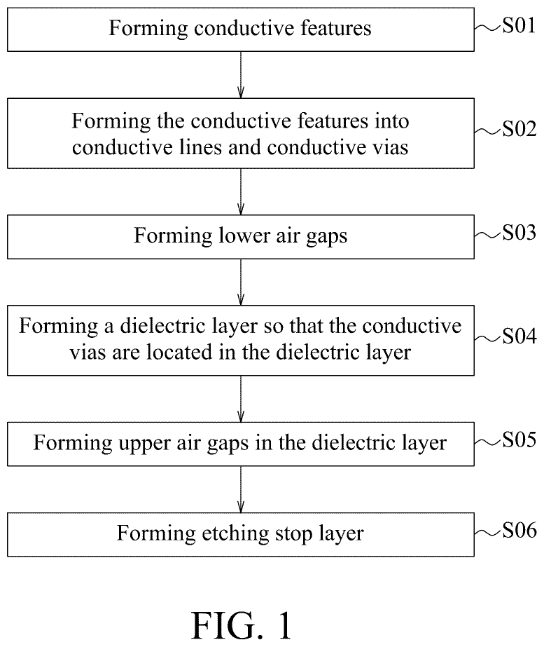

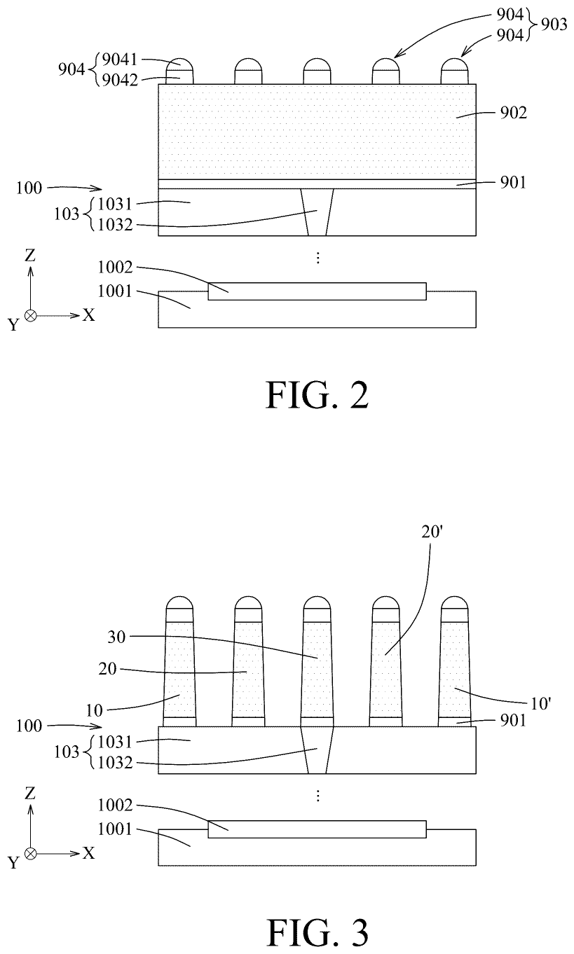

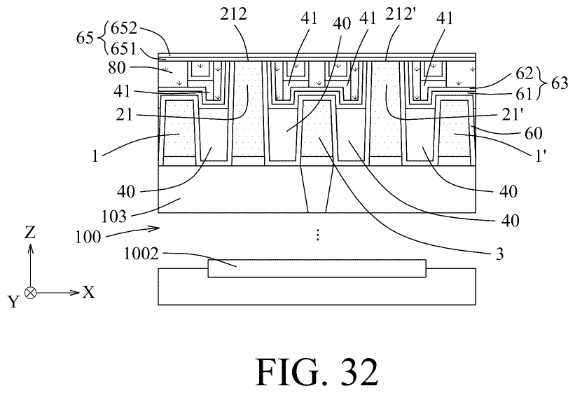

FIG. 1 is a flow diagram illustrating a method for manufacturing an interconnect structure (e.g., the interconnect structure shown in FIG. 32) which is formed on a base structure 100 in accordance with some embodiments. The method may include steps S01 to S06. FIGS. 2 to 32 are schematic views illustrating intermediate stages of the method in accordance with some embodiments.

Referring to FIG. 1 and the examples illustrated in FIGS. 2 and 3, the method begins at step S01, where a conductive feature 10, a conductive feature 20, and a conductive feature 30 are formed on a base structure 100. FIG. 3 is a schematic sectional view (an X-cut view) illustrating the conductive feature 10, the conductive feature 20, the conductive feature 30, a conductive feature 20′, a conductive feature 10′, and the base structure 100 located therebeneath in accordance with some embodiments. FIG. 2 (which is also an X-cut view) and FIG. 3 respectively illustrate possible intermediate stages in step S01 in accordance with some embodiments.

In some embodiments, the base structure 100 is a device wafer including active devices (for example, transistors, diodes, or the like), passive devices (for example, capacitors, inductors, resistors, or the like), memory devices, decoders, amplifiers, or combinations thereof. In some embodiments, the base structure 100 includes a substrate 1001, a plurality of semiconductor devices 1002 (one of which is exemplarily shown in FIG. 2) formed on the substrate 1001, and an interconnect layer 103 formed on the semiconductor devices 1002.

In some embodiments, the substrate 1001 may include elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the substrate 1001 may be a bulk semiconductor substrate, for example, but not limited to, a bulk substrate of silicon, germanium, silicon germanium, or other suitable semiconductor materials (such as the examples described earlier in the same paragraph). In some other embodiments not shown herein, the substrate 1001 may be configured as a semiconductor-on-insulator substrate. Other suitable materials and configurations for the substrate 1001 are within the contemplated scope of the present disclosure. In some embodiments, the substrate 1001 may be formed with trench isolations (not shown) to separate each of the semiconductor devices 1002 from adjacent ones of the semiconductor devices. In some embodiments, the trench isolations may each be a shallow trench isolation (STI), a deep trench isolation (DTI), or other suitable structures. In some embodiments, the trench isolations may include silicon oxide, silicon nitride, silicon oxynitride, other low-k (low-dielectric constant) dielectric materials, or combinations thereof.

In some embodiments, the semiconductor devices 1002 may each include a transistor, but is not limited thereto. The transistor may be configured as a planar transistor, a fin-type field-effect transistor (FinFET), a gate-all-around field-effect transistor (GAAFET), a forksheet field-effect transistor, a complementary field-effect transistor (CFET), or other transistors with suitable configuration.

In some embodiments, the interconnect layer 103 includes a dielectric layer 1031 and conductive features 1032 (one of which is exemplarily shown in FIG. 2) formed in the dielectric layer 1031. The semiconductor devices 1002 may be each electrically connected to an external circuit through the conductive features 1032. In some embodiments, the dielectric layer 1031 includes or is made of a low-k dielectric material. In some embodiments, the dielectric layer 1031 includes or is made of silicon oxide, silicon oxycarbide, silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOC), spin-on-glass (SOG), fluorine-doped silicon oxide, carbon-doped silicon oxide, porous silicon oxide, porous carbon-doped silicon oxide, other suitable low-k dielectric materials, or combinations thereof. Other dielectric materials suitable for the dielectric layer 1031 are within the contemplated scope of the present disclosure. In some embodiments, the conductive features 1032 may be each configured as a conductive via which is connected to a conductive line (not shown) that is located therebeneath, and in such case, additional interconnect layer(s) (not shown) may be formed between the interconnect layer 103 and the semiconductor devices 1002. In some other embodiments, the conductive features 1032 may be each configured as a conductive contact which is connected to a gate electrode or a source/drain portion of a corresponding one of the semiconductor devices 1002. In some embodiments, each of the conductive features 1032 includes or is made of Cu, Co, Ru, Mo, Cr, W, Mn, Rh, Ir, Ni, Pd, Ag, Au, Al, alloys thereof, graphene, or combinations thereof. Other conductive materials suitable for the conductive features 1032 are also within the contemplated scope of the present disclosure. In some embodiments, the conductive features 1032 may be formed by a single damascene process involving physical vapor deposition (hereinafter PVD), chemical vapor deposition (hereinafter CVD), atomic layer deposition (hereinafter ALD) or other suitable processes. In some embodiments, each of the conductive features 1032 has a thickness (measured in an upright direction (Z)) ranging from about 50 Å to about 500 Å, but other ranges of values are also within the contemplated scope of the present disclosure.

Referring to FIG. 2, a conductive layer 902 is formed on the base structure 100, and then a patterned mask 903 is formed on the conductive layer 902. In some embodiments, a glue layer 901 is formed between the conductive layer 902 and the base structure 100. In some embodiments, the glue layer 901 includes or is made of Ta, Ti, tantalum nitride, titanium nitride, other metal nitride, other suitable materials, or combinations thereof. In some embodiments, the glue layer 901 may be formed by a suitable deposition process such as PVD, CVD, or ALD or combinations thereof. In the following description, a deposition process, unless otherwise stated or defined in this disclosure, may be performed in a way similar to the above-mentioned ones. In some embodiments, the glue layer 901 has a thickness ranging from about 2 Å to about 100 Å, but other ranges of values are also within the contemplated scope of the present disclosure. The conductive layer 902 includes or is made of Cu, Co, Ru, Mo, Cr, W, Mn, Rh, Ir, Ni, Pd, Ag, Au, Al, alloys thereof, graphene, other suitable materials, or combinations thereof. In some embodiments, the conductive layer 902 includes or is made of Ru. The patterned mask 903 includes mask parts 904 that are elongated in a lengthwise direction (Y) transverse to (e.g., perpendicular to) the upright direction (Z) and that are spaced apart from each other in a transverse direction (X) transverse to (e.g., perpendicular to) the lengthwise direction (Y) and the upright direction (Z). Each of the mask parts 904 has an upper mask region 9041 and a lower mask region 9042. In some embodiments, for each of the mask parts 904, the upper mask region 9041 is a hard mask for patterning, and the lower mask region 9042 is a polishing stop layer or a hard mask and includes or is made of a material different from the upper mask region 9041. In some embodiments, the patterned mask 903 may be formed by depositing two different dielectric layers respectively for forming the upper and lower mask regions 9041, 9042 of the mask parts 904 on the conductive layer 902 opposite to the base structure 100, followed by a patterning process for patterning the two different dielectric layers into the upper and lower mask regions 9041, 9042 of the mask parts 904. In some embodiments, the patterning process includes a photolithography process and a subsequent etching process. The photolithography process may include: forming a photoresist layer over a structure to be patterned by, for example, spin coating; and patterning the photoresist layer using a photomask or without a mask (e.g., ion-beam writing). The etching process, which utilizes the patterned photoresist layer as an etching mask, may include etching the structure to be patterned by, for example, dry etching, wet etching, or a combination thereof. In the following description, a patterning process, a photolithography process or an etching process, unless otherwise stated or defined in this disclosure, may be performed in a way similar to the above-mentioned ones.

Referring to FIG. 3, the conductive layer 902 (see FIG. 2) is patterned into a plurality of conductive features 10, 20, 30, 20′, 10′ through the patterned mask 903 (see FIG. 2) using a suitable etching process, such as dry etching, wet etching, or a combination thereof. The glue layer 901 is also patterned in this process. Because the mask parts 904 (see FIG. 2) are elongated in the lengthwise direction (Y) and are spaced apart from each other in the transverse direction (X), the conductive features 10, 20, 30, 20′, 10′ are elongated in the lengthwise direction (Y) and are spaced apart from each other in the transverse direction (X).

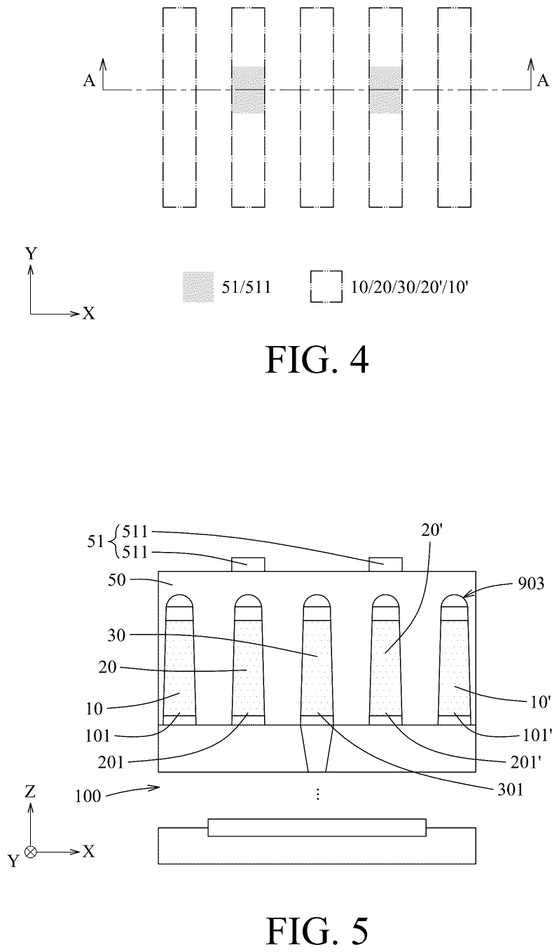

Referring to FIG. 1 and the examples illustrated in FIGS. 4 to 7, the method proceeds to step S02, where the conductive features 10, 30, 10′ are respectively formed into conductive lines 1, 3, 1′, and each of the conductive features 20, 20′ is formed into a conductive line 2 or 2′ and a conductive via 21 or 21′. FIGS. 5, 6 and 7 are each an X-cut view subsequent to FIG. 3 and illustrate three possible intermediate stages in step S02 in accordance with some embodiments. FIG. 4 is a schematic layout diagram illustrating a positional relationship between the conductive features 10, 20, 30, 20′, 10′ and a patterning mask 51 for patterning the conductive features 10, 20, 30, 20′, 10′ in accordance with some embodiments, but other elements are omitted. FIG. 5 is a schematic sectional view (an X-cut view) taken along line A-A of FIG. 4 to illustrate the conductive features 10, 20, 30, 20′, 10′ and the base structure 100 located therebeneath in accordance with some embodiments. In some embodiments, step S02 may include multiple sub-steps as described in the following.

Referring to FIG. 5, a filling material layer 50 is formed over the patterned mask 903 and the conductive features 10, 20, 30, 20′, 10′ on the base structure 100 by any suitable deposition process to fill a space among the conductive features 10, 20, 30, 20′, 10′, and then the patterning mask 51 is formed on the filling material layer 50. The patterning mask 51 covers a portion of each of the conductive features 20, 20′, and has masking portions 511 which are respectively in positions corresponding to positions where the conductive vias 21, 21′ are to be formed. Each of the conductive features 10, 20, 30, 20′, 10′ has a base end 101, 201, 301, 201′, 101′ that is adjacent to the base structure 100. Since, in some embodiments, each of the conductive features 10, 20, 30, 20′, 10′ has a taper shape in the X-cut view (FIG. 5), the base ends 101, 201, 301, 201′, 101′ of the conductive features 10, 20, 30, 20′, 10′ shown in FIG. 5 are used to illustrate the positions and dimensions of the conductive features 10, 20, 30, 20′, 10′ in the schematic layout diagram (FIG. 4). In addition, in FIG. 4, the conductive features 10, 20, 30, 20′, 10′ are shown in dot-dot-dash lines, and the masking portions 511 are gray shaded. In some embodiments, the filling material layer 50 may be a bottom anti-reflection coating (hereinafter BARC), which is a layer of porous polymer made from styrene monomers and epoxy crosslinkers. In some embodiments, the patterning mask 51 may be a patterned photoresist layer made using a suitable photolithography process. Other suitable materials and processes for forming the filling material layer 50 and the patterning mask 51 are within the contemplated scope of the present disclosure.

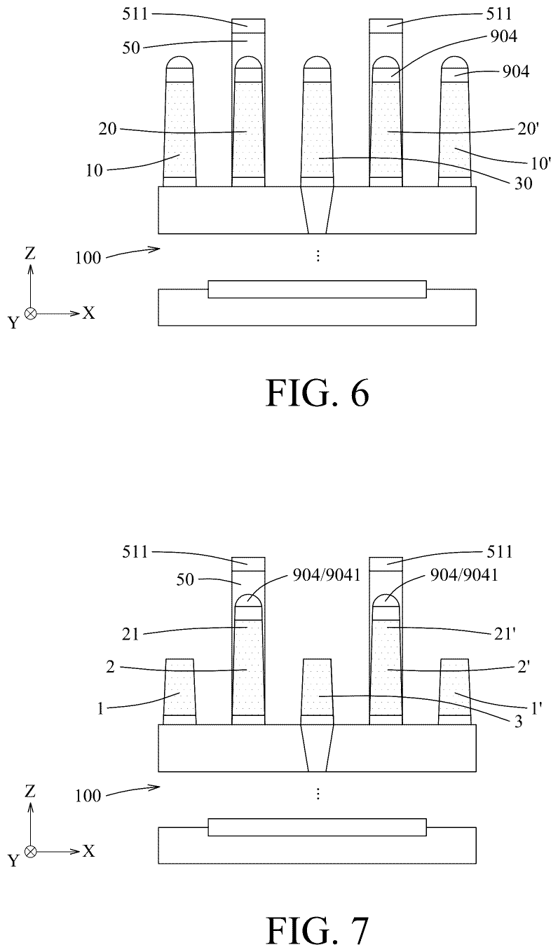

Afterwards, as shown in FIGS. 6 and 7, a patterning process is performed such that the conductive features 10, 20, 30, 20′, 10′ are patterned into the conductive lines 1, 2, 3, 2′, 1′ and the conductive vias 21, 21′ through the patterning mask 51. The number of the conductive lines 1, 2, 3, 2′, 1′ and the number of the conductive vias 21 and 21′ are not limited to the numbers shown in FIG. 7, and may vary according to practical applications.

In some embodiments, the patterning process may be performed as follows. Firstly, as shown in FIG. 6, portions of the filling material layer 50 which are exposed from the masking portions 511 are removed using any suitable etching process. Afterwards, as shown in FIG. 7, the mask parts 904 (see FIG. 6) exposed from the masking portions 511 are removed, and then, the conductive features 10, 20, 30, 20′, 10′ are formed into the conductive lines 1, 2, 3, 2′, 1′ and the conductive vias 21, 21′ by any suitable etching process, which utilizes the remaining filling material layer 50 and the masking portions 511 as an etching mask. The conductive vias 21, 21′ are respectively formed on the conductive lines 2, 2′ opposite to the base structure 100 in the upright direction (Z).

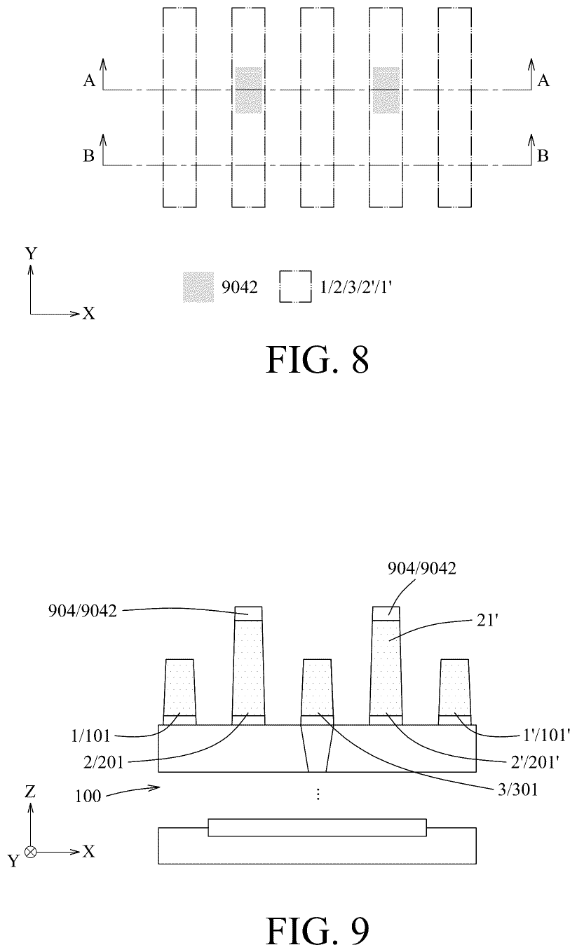

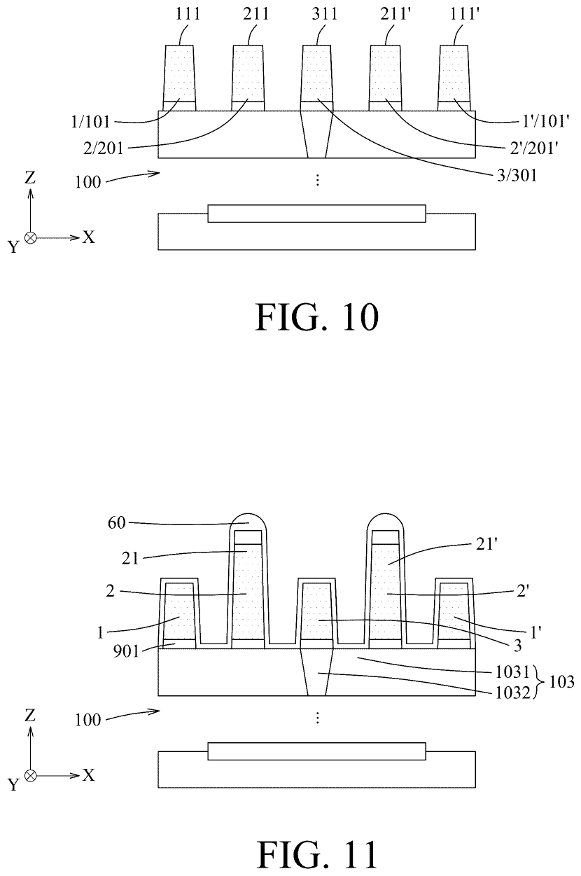

In some embodiments, after the patterning process, step S02 may further include a sub-step of removing the masking portions 511, the remaining filling material layer 50, and the upper mask regions 9041 (see FIG. 7) of the remaining mask parts 904 sequentially using an etching process, an ashing process, other suitable processes, or combinations thereof, so as to obtain a structure as illustrated in FIGS. 8 to 10. FIG. 8 is a schematic layout of the conductive lines 1, 2, 3, 2′, 1′, in which the base ends 101, 201, 301, 201′, 101′ shown in FIGS. 9 and 10 are shown in dot-dot-dash lines, and in which upper surfaces of the lower mask regions 9042 of the remaining mask parts 904 shown in FIG. 9 are gray shaded, but other elements are omitted. The lower mask regions 9042 of the remaining mask parts 904 respectively cover upper surfaces of the conductive vias 21, 21′ (see FIG. 9), and thus, positions of the lower mask regions 9042 in FIG. 8 may substantially represent positions of the upper surfaces of the conductive vias 21, 21′, respectively. FIG. 9 is a schematic sectional view (an X-cut view) taken along line A-A of FIG. 8 to illustrate the conductive vias 21, 21′, the conductive lines 1, 2, 3, 2′, 1′ and the base structure 100 located therebeneath in accordance with some embodiments. FIG. 10 is a schematic sectional view (an X-cut view) taken along line B-B of FIG. 8 to illustrate the conductive lines 1, 2, 3, 2′, 1′ and the base structure 100 located therebeneath in accordance with some embodiments. Each of the conductive lines 1, 2, 3, 2′, 1′ is elongated in the lengthwise direction (Y). The conductive lines 1, 2, 3, 2′, 1′ are spaced apart from each other in the transverse direction (X).

In some embodiments, the conductive lines 1, 2, 3, 2′, 1′ and the conductive vias 21, 21′ are formed from the conductive layer 902 by the processes as described in steps S01 and S02, and are formed by the same etching process illustrated by FIG. 7. In some other embodiments, the conductive lines 1, 2, 3, 2′, 1′ may be formed before forming the conductive vias 21, 21′. For example, after forming the conductive lines 1, 2, 3, 2′, 1′, a sacrificial material, which may include or be made of a polymer material, may be filled between any two adjacent ones of the conductive lines 1, 2, 3, 2′, 1′, and then the conductive vias 21, 21′ are formed respectively on the conductive lines 2, 2′ followed by removing the sacrificial material. Other suitable processes for forming the conductive lines 1, 2, 3, 2′, 1′ and the conductive vias 21, 21′ are within the contemplated scope of the present disclosure.

In some embodiments, each of the conductive lines 1, 2, 3, 2′, 1′ and the conductive vias 21, 21′ has a thickness (measured in an upright direction (Z)) ranging from about 50 Å to about 500 Å, but other ranges of values are also within the contemplated scope of the present disclosure.

Referring to FIG. 1, and the examples illustrated in FIGS. 11 to 15, the method proceeds to step S03, where air gaps 40, which may be also referred to as lower air gaps, are formed. In some embodiments, formation of the air gaps 40 may include multiple sub-steps as described in the following. FIGS. 11 to 15 are each an X-cut view subsequent to FIG. 9 and illustrate four possible intermediate stages in step S03 in accordance with some embodiments.

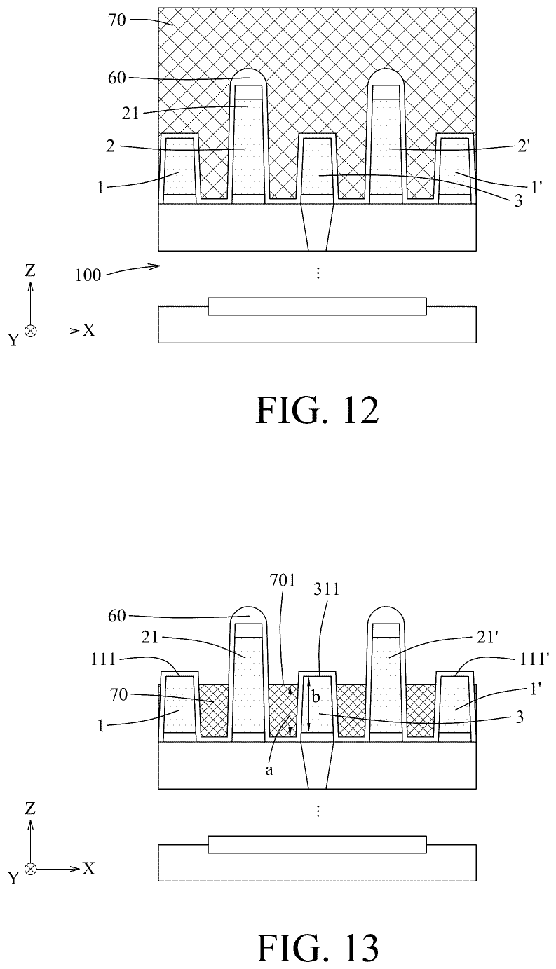

Firstly, as shown in FIG. 11, a dielectric capping layer 60 is formed over the conductive lines 1, 2, 3, 2′, 1′, and the conductive vias 21, 21′ on the base structure 100. In some embodiments, the dielectric capping layer 60 may include or be made of silicon oxide, silicon oxycarbide, silicon oxynitride, silicon carbonitride, silicon oxycarbonitride, aluminum nitride, aluminum oxynitride, aluminum oxide, other suitable materials, or combinations thereof. In some embodiments, the dielectric capping layer 60 may be formed by PVD, CVD, ALD, plasma-enhanced CVD (hereinafter PECVD), plasma-enhanced ALD (hereinafter PEALD), or other suitable processes, and may provide good adhesion to the conductive lines 1, 2, 3, 2′, 1′, the conductive vias 21, 21′, and the glue layer 901. In some embodiments, the dielectric capping layer 60 has a thickness ranging from about 2 Å to about 50 Å, but other ranges of values are also within the contemplated scope of the present disclosure. The glue layer 901 provides good adhesion to the interconnect layer 103 and the dielectric capping layer 60. Next, as shown in FIG. 12, a sacrificial layer 70 is formed over the dielectric capping layer 60. In some embodiments, the sacrificial layer 70 may be an organic layer including C, O, N, and H. In some embodiments, the sacrificial layer 70 includes or is made of polyurea, polylactic acid, polycaprolactone, poly(ethylene oxide), polyacrylate, polyvinyl alcohol, other suitable materials, or combinations thereof, but is not limited thereto. In some embodiments, the sacrificial layer 70 may be formed by CVD, ALD, molecular layer deposition (hereinafter MLD), a spin-on process, or combinations thereof, and a thickness thereof in the upright direction (Z) may be tuned by a thermal recess process, an etching back process (such as dry etching, wet etching or a combination thereof), or other suitable processes. Afterwards, as shown in FIG. 13, the sacrificial layer 70 is recessed so that an upper portion of the dielectric capping layer 60, which is formed over the conductive vias 21, 21′, is exposed from the recessed sacrificial layer 70. In some embodiments, the sacrificial layer 70 may be recessed by a thermal baking process, an ultraviolet (hereinafter UV) curing process, both the thermal baking process and the UV curing process, or other suitable processes. In some embodiments, the recessed sacrificial layer 70 has a thickness (a) ranging from about 10 Å to about 100 Å, but other ranges of values are also within the contemplated scope of the present disclosure. Referring to FIGS. 10 and 13, in some embodiments, an upper surface 701 of the recessed sacrificial layer 70 is at a level lower than a level of an upper surface 111, 211, 311, 211′, 111′ of each of the conductive lines 1, 2, 3, 2, 1′, and a ratio of the thickness (a) of the sacrificial layer 70 to a height (b) of each of the conductive lines 1, 2, 3, 2′, 1′ in the upright direction (Z) ranges from about 1:5 to about 4:5. If the ratio is less than about 1:5, the air gaps 40 (see FIG. 15) to be formed hereafter may have a relatively low volume, and thus the effectiveness of reducing parasitic capacitance may be insufficient. If the ratio is greater than about 4:5, the structure of the air gaps 40 may be unstable.

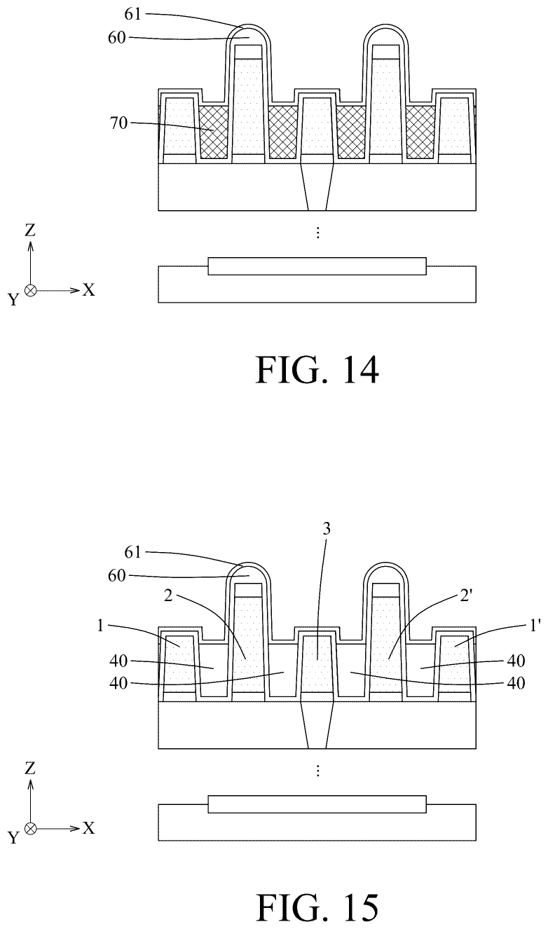

Afterwards, as shown in FIG. 14, a porous dielectric film 61 is formed over the recessed sacrificial layer 70 and the upper portion of the dielectric capping layer 60 to serve as a sustaining layer. In some embodiments, the porous dielectric film 61 includes or is made of silicon oxide, silicon oxycarbide, silicon oxynitride, silicon carbonitride, silicon carbon oxynitride, other suitable materials, or combinations thereof, and has a thickness ranging from about 2 Å to about 100 Å, but other ranges of values are also within the contemplated scope of the present disclosure. In some embodiments, the porous dielectric film 61 may be formed by PVD, CVD, ALD, PECVD, PEALD, or other suitable processes, and may provide good mechanical strength to maintain robustness of an air-gap structure. Referring to FIG. 15, after the porous dielectric film 61 is formed, the recessed sacrificial layer 70 is removed, thereby forming the air gaps 40. Each of the air gaps 40 is located between two adjacent ones of the conductive lines 1, 2, 3, 2′, 1′.

In some embodiments, the recessed sacrificial layer 70 may be removed by a thermal treatment, an ultraviolet treatment, other suitable treatments, or combinations thereof so as to permit the recessed sacrificial layer 70 to be decomposed, vaporized, and degassed through the porous dielectric film 61. In some embodiments, the porous dielectric film 61 may collapse after removal of the recessed sacrificial layer 70 when the porous dielectric film 61 is too thin (e.g., thinner than about 2 Å), and the recessed sacrificial layer 70 may not be removed easily when the porous dielectric film 61 is too thick (e.g., thicker than about 100 Å). In some embodiments, decomposition of the recessed sacrificial layer 70 is executed at a temperature ranging from about 250° C. to about 350° C. Process parameters (for example, but not limited to, temperature, time period, etc.) for decomposition of the recessed sacrificial layer 70 may be adjusted according to the selection of polymers for forming the recessed sacrificial layer 70 and in consideration of thermal budget of the structure shown in FIG. 14 such that less residue of the recessed sacrificial layer 70 remains in the structure.

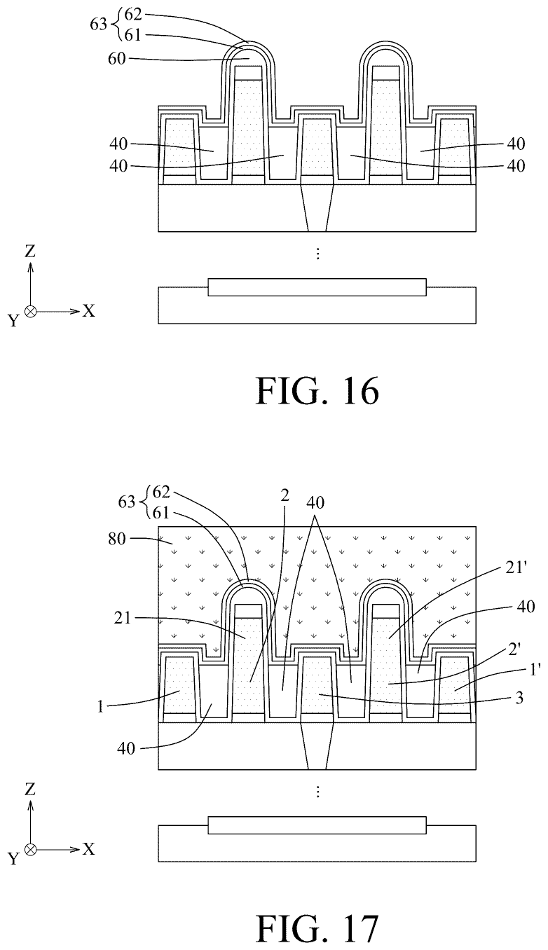

Referring to FIG. 1, and the examples illustrated in FIGS. 16 and 17, the method proceeds to step S04, where a dielectric layer 80 is formed so that the conductive vias 21, 21′ are located in the dielectric layer 80. FIGS. 16 and 17 are each an X-cut view subsequent to FIG. 15 and illustrate two possible intermediate stages in step S04 in accordance with some embodiments. In some embodiments, formation of the dielectric layer 80 may include multiple sub-steps as described in the following.

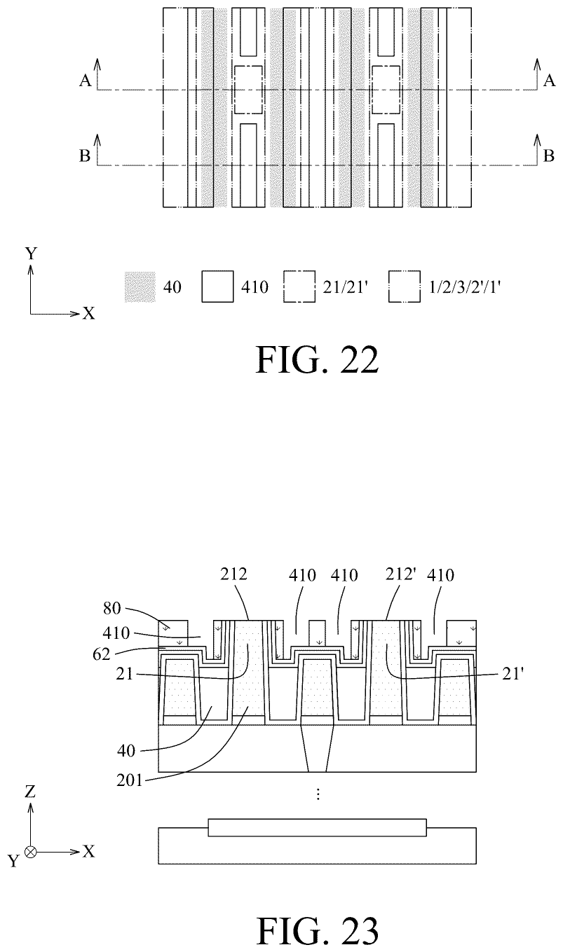

Firstly, referring to FIG. 16, an aluminum-based dielectric film 62 is formed over the porous dielectric film 61 (i.e., the aluminum-based dielectric film 62 is formed after removing the recessed sacrificial layer 70). In other embodiments, the aluminum-based dielectric film 62 may be formed before removing the recessed sacrificial layer 70 so that the recessed sacrificial layer 70 is degassed through the porous dielectric film 61 and the aluminum-based dielectric film 62. In some embodiments, the aluminum-based dielectric film 62 may serve as an etching stop layer during an etching process for forming a structure illustrated by FIGS. 22 to 24. In some embodiments, the aluminum-based dielectric film 62 includes or is made of aluminum oxide, aluminum nitride, aluminum oxycarbide, other suitable materials, or combinations thereof, and has a thickness ranging from about 10 Å to about 30 Å, but other ranges of values are also within the contemplated scope of the present disclosure. In some embodiments, the aluminum-based dielectric film 62 may be broken through in the etching process for forming the structure illustrated by FIGS. 22 to 24 when the aluminum-based dielectric film 62 is too thin (e.g., thinner than about 10 Å), and the parasitic capacitance may be increased when the aluminum-based dielectric film 62 is too thick (e.g., thicker than about 30 Å). In some embodiments, the aluminum-based dielectric film 62 may be formed by ALD, MLD, other suitable processes, or combinations thereof. The porous dielectric film 61 and the aluminum-based dielectric film 62 cooperatively serve as a protection layer 63. The protection layer 63 is disposed to entirely separate the dielectric layer 80 (see FIG. 17) from the conductive lines 1, 2, 3, 2′, 1′, the conductive vias 21, 21′ and the air gaps 40, and includes a material different from a material of the dielectric layer 80. In other words, the material of each of the porous dielectric film 61 and the aluminum-based dielectric film 62 is different from the material of the dielectric layer 80. Afterwards, referring to FIG. 17, the dielectric layer 80 is formed on the protection layer 63 (i.e., the dielectric layer 80 is formed over the conductive lines 1, 2, 3, 2′, 1′, the conductive vias 21, 21′ and the air gaps 40). In some embodiments, the dielectric layer 80 may be a low-k dielectric layer including Si, C, O and H. In some embodiments, the dielectric layer 80 includes or is made of silicon oxide, silicon nitride, silicon oxycarbide (which may be also referred to as oxygen-doped siliconcarbide, abbreviated as ODC or SiOC), silicon oxynitride (SiON), silicon carbon nitride (which may be also referred to as nitrogen-doped silicon carbide, abbreviated as NDC or SiCN), silicon oxide formed from tetraethoxysilane (TEOS), or combinations thereof. Other low-k dielectric materials suitable for the dielectric layer 80 are within the contemplated scope of the present disclosure. In some embodiments, the dielectric layer 80 may be formed by CVD, ALD, a spin-on process, or other suitable processes, may provide good adhesion to the aluminum-based dielectric film 62, and has a thickness ranging from about 10 Å to about 700 Å, but other ranges of values are also within the contemplated scope of the present disclosure.

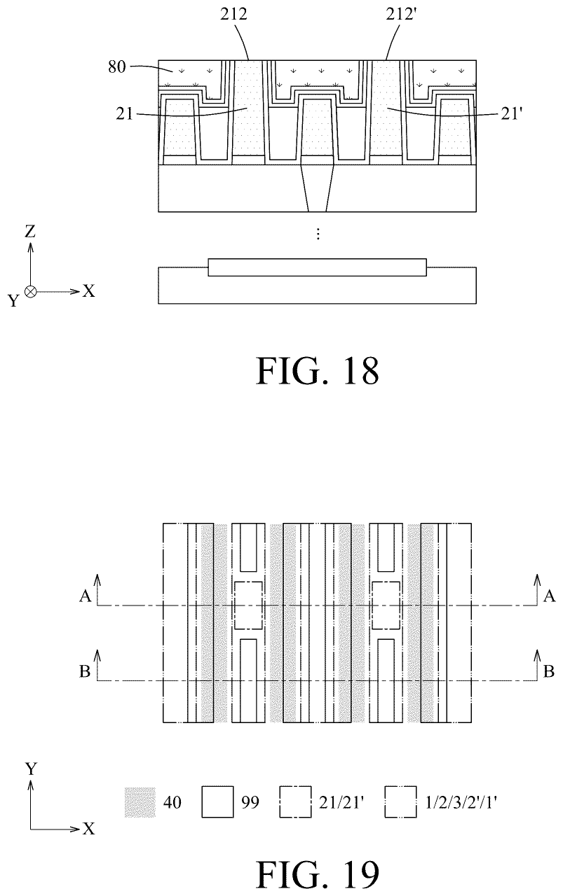

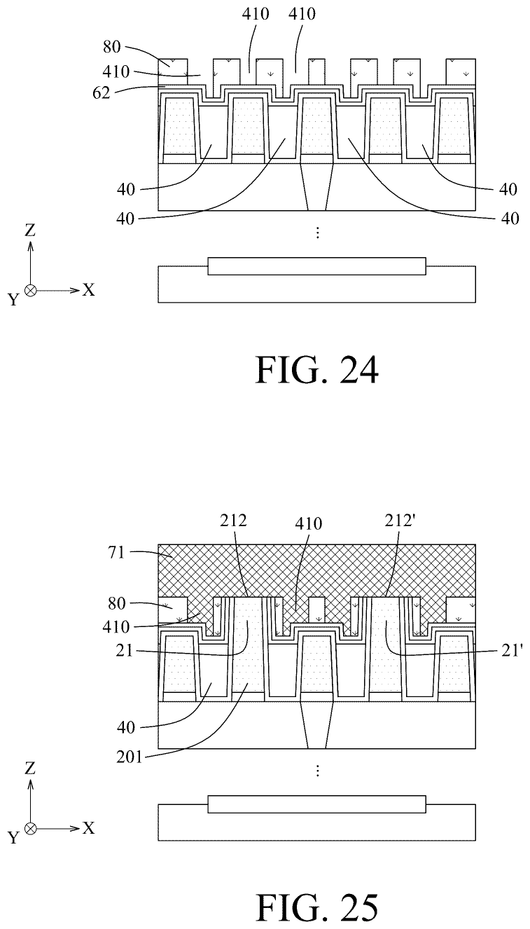

Referring to FIG. 1 and the examples illustrated in FIGS. 18 to 31, the method proceeds to step S05, where air gaps 41, 42, which may be also referred to as upper air gaps, are formed in the dielectric layer 80. FIGS. 18, 20, 23, 25 to 28 and 30 to 31 are each an X-cut view subsequent to FIG. 17, FIGS. 19, 22 and 29 are each a schematic layout diagram subsequent to FIG. 8, and FIGS. 21 and 24 are each an X-cut view subsequent to FIG. 10. FIGS. 18 to 31 are provided for illustrating possible intermediate stages in step S05 in accordance with some embodiments. In some embodiments, formation of the air gaps 41, 42 may include multiple sub-steps as described in the following.

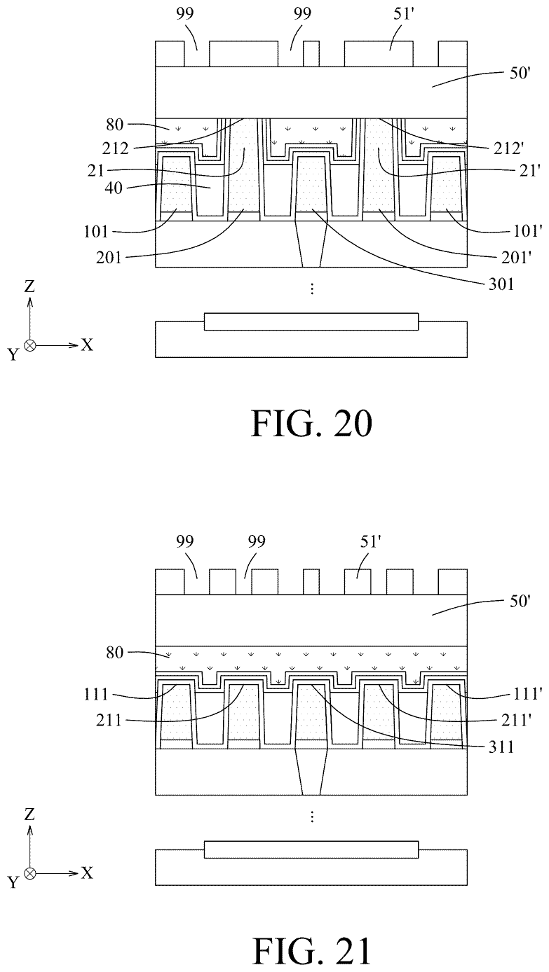

Firstly, as shown in FIG. 18, a planarization process (e.g., a chemical mechanical polishing process) is performed on the dielectric layer 80 until upper surfaces 212, 212′ of the conductive vias 21, 21′ are exposed from the planarized dielectric layer 80. Then, referring to FIGS. 20 and 21, another filling material layer 50′ is formed over the planarized dielectric layer 80 and the upper surfaces 212, 212′ of the conductive vias 21, 21′, and then another patterning mask 51′ is formed on the filling material layer 50′. The patterning mask 51′ covers a portion of the filling material layer 50′, and a plurality of gaps 99 are formed through the patterning mask 51′ such that a remaining portion of the filling material layer 50′ which is not covered by the patterning mask 51′ is exposed. Suitable materials and processes for forming the filling material layer 50′ and the patterning mask 51′ are respectively similar to those for forming the filling material layer 50 and the patterning mask 51 described with reference to FIG. 5, and thus the details thereof are omitted for the sake of brevity. FIG. 19 is a schematic layout diagram illustrating a positional relationship among the air gaps 40, the gaps 99, the conductive vias 21, 21′ and the conductive lines 1, 2, 3, 2′, 1′ in accordance with some embodiments, in which the planarized dielectric layer 80 (see FIGS. 20 and 21), the filling material layer 50′ (see FIGS. 20 and 21), the patterning mask 51′ (see FIGS. 20 and 21) for patterning the planarized dielectric layer 80, and other elements therebeneath are omitted. FIG. 20 is a schematic sectional view (an X-cut view) taken along line A-A of FIG. 19 in accordance with some embodiments but further illustrating the omitted elements. FIG. 21 is a schematic sectional view (an X-cut view) taken along line B-B of FIG. 19 in accordance with some embodiments but further illustrating the omitted elements. Since, in some embodiments, each of the conductive vias 21, 21′ has a taper shape in the X-cut view (FIG. 20), the upper surfaces 212, 212′ of the conductive vias 21, 21′ shown in FIG. 20 are used to illustrate the positions and dimensions of the conductive vias 21, 21′ in the schematic layout diagram (FIG. 19).

In the schematic layout diagram shown in FIG. 19, the conductive lines 1, 2, 3, 2′, 1′ are shown in dot-dot-dash lines, the air gaps 40 are gray shaded, the gaps 99 are shown in solid lines, and the upper surfaces 212, 212′ of the conductive vias 21, 21′ are shown in dot-dash lines.

Afterwards, the filling material layer 50′ and the planarized dielectric layer 80 (see FIGS. 20 and 21) are patterned by any suitable etching process using the patterning mask 51′ as an etching mask, followed by removing the filling material layer 50′ and the patterning mask 51′ so as to obtain a structure illustrated by FIGS. 22 to 24 in which a plurality of recesses 410 are formed. In this etching process, the aluminum-based dielectric film 62 may serve as an etching stop layer. As shown in FIG. 22, two of the recesses 410 are located at two opposite sides of the conductive via 21 in the transverse direction (X), two of the recesses 410 are located at two opposite sides of the conductive via 21 in the lengthwise direction (Y), two of the recesses 410 are located at two opposite sides of the conductive via 21′ in the transverse direction (X), and two of the recesses 410 are located at two opposite sides of the conductive via 21′ in the lengthwise direction (Y). In other words, each of the conductive vias 21, 21′ is located among four of the recesses 410. In the schematic layout diagram shown in FIG. 22, the conductive lines 1, 2, 3, 2′, 1′ are shown in dot-dot-dash lines, the air gaps 40 are gray shaded, the recesses 410 are shown in solid lines, the conductive vias 21, 21′ are shown in dot-dash lines, and other elements are omitted. The recesses 410 occupy the same positions in FIG. 22 as the positions of the gaps 99 in FIG. 19. FIG. 23 is a schematic sectional view (an X-cut view) taken along line A-A of FIG. 22 in accordance with some embodiments but further illustrating the omitted elements. FIG. 24 is a schematic sectional view (an X-cut view) taken along line B-B of FIG. 22 in accordance with some embodiments but further illustrating the omitted elements.

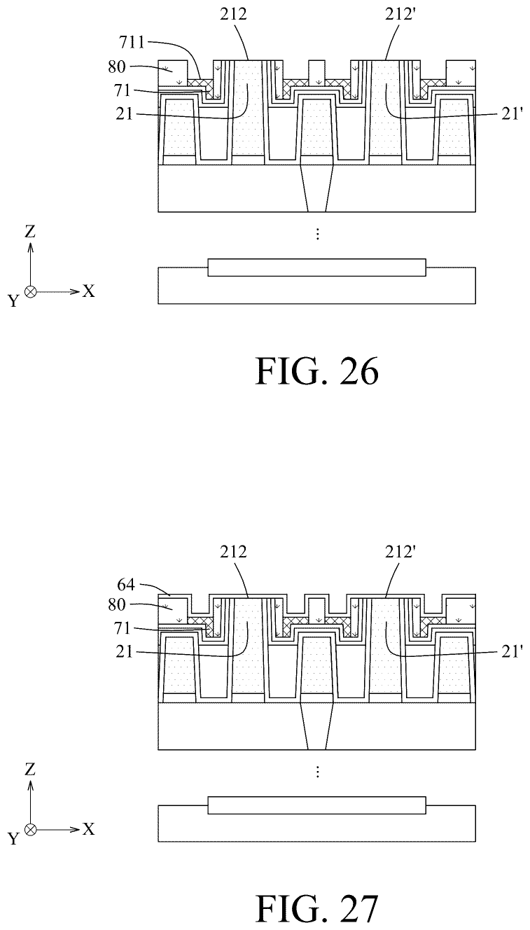

Next, as shown in FIG. 25, a sacrificial layer 71 is formed over the planarized dielectric layer 80 and the upper surfaces 212, 212′ of the conductive vias 21, 21′, and is formed to fill the recesses 410. Suitable materials and processes for forming the sacrificial layer 71 are similar to those for forming the sacrificial layer 70, and thus details thereof are omitted for the sake of brevity. The material of the sacrificial layer 71 may be the same as or different from the material of the sacrificial layer 70. Afterwards, as shown in FIG. 26, the sacrificial layer 71 is recessed using any suitable processes for recessing the sacrificial layer 70 as described with reference to FIG. 13 so that the planarized dielectric layer 80 and the upper surfaces 212, 212′ of the conductive vias 21, 21′ are exposed from the recessed sacrificial layer 71 (i.e., an upper surface 711 of the recessed sacrificial layer 71 is at a level lower than a level of an upper surface of the planarized dielectric layer 80 and a level of the upper surfaces 212, 212′ of the conductive vias 21, 21′ in the upright direction (Z)).

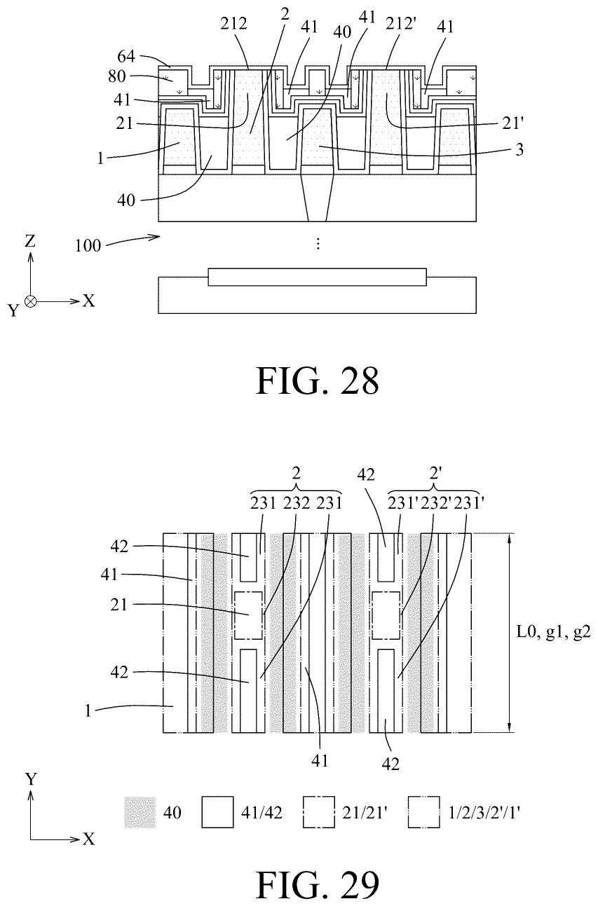

Afterwards, as shown in FIG. 27, another porous dielectric film 64 is formed over the recessed sacrificial layer 71, the planarized dielectric layer 80, and the upper surfaces 212, 212′ of the conductive vias 21, 21′ to serve as a sustaining layer (i.e., a protection layer). Suitable materials and processes for forming the porous dielectric film 64 are similar to those for forming the porous dielectric film 61, and thus the details thereof are omitted for the sake of brevity. The material of the porous dielectric film 64 may be the same as or different from the material of the porous dielectric film 61. Referring to FIG. 28, after the porous dielectric film 64 is formed, the recessed sacrificial layer 71 (see FIG. 27) is removed, thereby forming the air gaps 41, 42 (see FIG. 29 for 42) in the planarized dielectric layer 80. Since the recessed sacrificial layer 71 may be removed in a manner similar to the process for removing the recessed sacrificial layer 70 as described with reference to FIGS. 14 and 15, the details thereof are omitted for the sake of brevity. For each of the conductive vias 21, 21′, there are two air gaps 41 that are formed in the planarized dielectric layer 80 and located at the two opposite sides thereof in the transverse direction (X), and two air gaps 42 (see FIG. 29) that are formed in the planarized dielectric layer 80 and located at the two opposite sides thereof in the lengthwise direction (Y).

Referring to FIGS. 22 and 29, the recesses 410 correspond respectively in position to the air gaps 41, 42. FIG. 29 is a schematic layout diagram illustrating a positional relationship among the conductive lines 1, 2, 3, 2′, 1′, the air gaps 40, 41, 42, and the conductive vias 21, 21′ in accordance with some embodiments but other elements are omitted. In the schematic layout diagram shown in FIG. 29, the conductive lines 1, 2, 3, 2′, 1′ are shown in dot-dot-dash lines, the air gaps 40 are gray shaded, the air gaps 41, 42 are shown in solid lines, and the conductive vias 21, 21′ are shown in dot-dash lines. Referring to FIG. 29, each of the conductive lines 2, 2′ has two elongated parts 231, 231′, and a connected part 232, 232′ that is connected to the conductive via 21, 21′ thereon and between the two elongated parts 231, 231′ thereof. For each of the conductive lines 2, 2′, two of the air gaps 42 are formed directly above the two elongated parts 231, 231′ thereof, respectively. In addition, each of the air gaps 40 has a length (g1) in the lengthwise direction (Y), each of the air gaps 41 has a length (g2) in the lengthwise direction (Y), and the length (g1) is equal to the length (g2). In addition, each of the conductive lines 1, 2, 3, 2′, 1′ has a length (L0) in the lengthwise direction (Y), which is equal to each of the length (g1) and the length (g2).

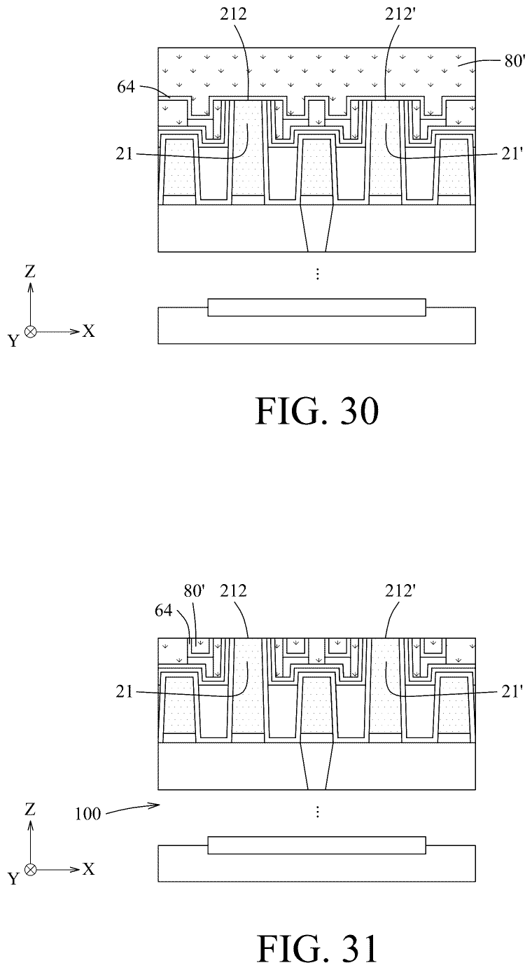

Afterwards, referring to FIG. 30, another dielectric layer 80′ is formed on the porous dielectric film 64. Suitable materials and processes for forming the dielectric layer 80′ are similar to those for forming the dielectric layer 80, and thus the details thereof are omitted for the sake of brevity. The material of the dielectric layer 80′ may be the same as or different from the material of the dielectric layer 80. Then, as shown in FIG. 31, a planarization process (e.g., a chemical mechanical polishing process) is performed on the dielectric layer 80′ until the upper surfaces 212, 212′ of the conductive vias 21, 21′ are exposed from the planarized dielectric layer 80′.

In some embodiments, the dielectric capping layer 60, the porous dielectric film 61, the aluminum-based dielectric film 62, and the porous dielectric film 64 are each a uniform layer having a conformity greater than about 90% for the dielectric layers 80, 80′ or the sacrificial layers 70, 71 to fill gaps thereamong. In such case, a minimum thickness of the uniform layer occupies at least about 90% of a maximum thickness thereof.

Referring to FIG. 1 and the examples illustrated in FIG. 32, the method proceeds to step S06, where an etching stop layer 65 is formed over the planarized dielectric layer 80, the upper surfaces 212, 212′ of the conductive vias 21, 21′, and the planarized dielectric layer 80′. The etching stop layer 65 may be configured as a single layer structure or a multi-layered structure. In some embodiments, the etching stop layer 65 is formed as a bi-layered structure including two sublayers 651, 652 made of different materials (e.g., aluminum nitride and silicon oxycarbide). In some embodiments, the material(s) for the etching stop layer 65 may include Si, C, O and H. In some embodiments, the etching stop layer 65 includes or is made of silicon oxycarbide, silicon oxycarbonitride, aluminum nitride, or combinations thereof, and aluminum nitride may be formed by thermal ALD or other suitable processes, and silicon oxycarbide and silicon oxycarbonitride may be formed by PECVD, PEALD, or other suitable processes.

Referring to FIG. 32, for each of the conductive lines 2, 2′, the air gaps 41 are respectively located directly above the air gaps 40, each of the air gaps 41 on the base structure 100 partially overlaps a projection of the respective one of the air gaps 40 on the base structure 100, and each of the air gaps 41 on the base structure 100 partially overlaps a projection of an adjacent corresponding one of the conductive line 1′ 1′ and the conductive line 3 on the base structure 100.

Referring to FIGS. 29 and 32, the air gaps 40 are formed in a trench part (around the conductive lines 1, 2, 3, 2′, 1′), and the air gaps 41, 42 are formed in a via part (around the conductive vias 21, 21′), and thus the parasitic capacitance is reduced. In some embodiments, a volume of the air gaps 40 occupies more than about 90% of a volume of the trench part (including the air gaps 40, a portion of the dielectric capping layer 60 and a portion of the protection layer 63 located among the conductive lines 1, 2, 3, 2′, 1′).

In some embodiments, some steps in the method may be modified, replaced, or eliminated without departure from the spirit and scope of the present disclosure. In some alternative embodiments, the interconnect structure may further include additional features, and/or some features present in the interconnect structure may be modified, replaced, or eliminated without departure from the spirit and scope of the present disclosure. Furthermore, other techniques suitable for forming air gaps in the interconnect structure may be integrated into the method of this disclosure.

In some embodiments, after step S06, an additional interconnect structure with or without air gaps may be formed on the interconnect structure shown in FIG. 32 using the method illustrated by FIG. 1 or other suitable techniques. Therefore, at least one of the conductive lines in the additional interconnect structure may be connected to a corresponding one of the conductive lines 1, 2, 3, 2′, 1′ through a corresponding one of the conductive vias (which may include the conductive vias 21, 21′ or other conductive vias not shown in the figures), thereby permitting a corresponding one of the semiconductor devices 1002 to be electrically connected to an external power source through the interconnect structures and the interconnect layer(s) 103 thereabove.

In some embodiments, the method illustrated by FIG. 1 may be applied for forming another interconnect structure in which the materials used therein and/or the aspect ratio and/or the pitch of the conductive lines are different from those illustrated in step S01 to S06.

In summary, by extending the air-gap scheme to both the via part and trench part of the interconnect structure, parasitic capacitance is reduced, thereby enhancing the functionality of microelectronic devices.

In accordance with some embodiments of the present disclosure, a method for manufacturing an interconnect structure includes: forming a first conductive line, a second conductive line, and a third conductive line on a base structure, the second conductive line being located between and spaced apart from the first conductive line and the third conductive line; forming a conductive via on the second conductive line opposite to the base structure; forming two lower air gaps each of which is located between the second conductive line and a respective one of the first conductive line and the third conductive line; forming a dielectric layer so that the conductive via is located in the dielectric layer; and forming two in the dielectric layer so that the two upper air gaps are located at two opposite sides of the conductive via.

In accordance with some embodiments of the present disclosure, the first conductive line, the second conductive line, the third conductive line and the conductive via are formed by: forming a first conductive feature, a second conductive feature and a third conductive feature on the base structure, the first conductive feature, the second conductive feature, and the third conductive feature being spaced apart from each other; forming a patterning mask which covers a portion of the second conductive feature; performing a patterning process to pattern the first conductive feature, the second conductive feature, and the third conductive feature through the patterning mask so that the first conductive feature is formed into the first conductive line, the second conductive feature is formed into the second conductive line and the conductive via, and the third conductive feature is formed into the third conductive line; and removing the patterning mask.

In accordance with some embodiments of the present disclosure, forming the two lower air gaps includes: forming a dielectric capping layer over the first conductive line, the second conductive line, the third conductive line, and the conductive via on the base structure; forming a first sacrificial layer over the dielectric capping layer; recessing the first sacrificial layer so that an upper portion of the dielectric capping layer, which is formed over the conductive via, is exposed from the recessed first sacrificial layer; forming a first porous dielectric film over the recessed first sacrificial layer and the upper portion of the dielectric capping layer; and after forming the first porous dielectric film, removing the recessed first sacrificial layer.

In accordance with some embodiments of the present disclosure, an upper surface of the recessed first sacrificial layer is at a level lower than a level of an upper surface of each of the first conductive line, the second conductive line and the third conductive line.

In accordance with some embodiments of the present disclosure, the first porous dielectric film includes silicon oxide, silicon oxycarbide, silicon oxynitride, silicon carbonitride or combinations thereof, and has a thickness ranging from 2 Å to 100 Å.

In accordance with some embodiments of the present disclosure, the method further includes: forming an aluminum-based dielectric film over the first porous dielectric film.

In accordance with some embodiments of the present disclosure, the aluminum-based dielectric film is formed after removing the recessed first sacrificial layer.

In accordance with some embodiments of the present disclosure, the aluminum-based dielectric film includes aluminum oxide, aluminum nitride, aluminum oxycarbide, or combinations thereof, and has a thickness ranging from 10 Å to 30 Å.

In accordance with some embodiments of the present disclosure, after forming the dielectric layer, an upper surface of the conductive via is exposed from the dielectric layer.

In accordance with some embodiments of the present disclosure, forming the two upper air gaps includes: forming two recesses in the dielectric layer so that the two recesses are located at the two opposite sides of the conductive via; forming a second sacrificial layer over the dielectric layer and the conductive via so as to fill the two recesses; recessing the second sacrificial layer so that an upper surface of the recessed second sacrificial layer is at a level lower than a level of the upper surface of the conductive via; forming a second porous dielectric film over the recessed second sacrificial layer and the conductive via; and after forming the second porous dielectric film, removing the recessed second sacrificial layer.

In accordance with some embodiments of the present disclosure, a method for manufacturing an interconnect structure includes: forming a first conductive line, a second conductive line, and a third conductive line on a base structure, each of the first conductive line, the second conductive line and the third conductive line being elongated in a lengthwise direction, the second conductive line being located between and spaced apart from the first conductive line and the third conductive line in a transverse direction that is transverse to the lengthwise direction; forming a conductive via on the second conductive line opposite to the base structure in an upright direction transverse to both the lengthwise direction and the transverse direction; forming two first air gaps, each of which is located between the second conductive line and a respective one of the first conductive line and the third conductive line; forming a dielectric layer so that the conductive via is located in the dielectric layer; forming two second air gaps in the dielectric layer so that the two second air gaps are located at two opposite sides of the conductive via in the transverse direction; and forming two third air gaps in the dielectric layer so that the two third air gaps are located at another two opposite sides of the conductive via in the lengthwise direction.

In accordance with some embodiments of the present disclosure, a projection of each of the two second air gaps on the base structure partially overlaps a projection of a respective one of the two first air gaps on the base structure.

In accordance with some embodiments of the present disclosure, a projection of each of the two second air gaps on the base structure partially overlaps a projection of an adjacent corresponding one of the first conductive line and the third conductive line on the base structure.

In accordance with some embodiments of the present disclosure, the second conductive line has two elongated parts and a connected part that is connected to the conductive via and is between the two elongated parts, and the two third air gaps are formed directly above the two elongated parts of the second conductive line, respectively.

In accordance with some embodiments of the present disclosure, each of the two first air gaps has a first length in the lengthwise direction, each of the two second air gaps has a second length in the lengthwise direction, and the first length is equal to the second length.

In accordance with some embodiments of the present disclosure, each of the first conductive line, the second conductive line and the third conductive line has a length in the lengthwise direction, which is equal to each of the first length and the second length.

In accordance with some embodiments of the present disclosure, an interconnect structure includes: a first conductive line, a second conductive line and a third conductive line, which are formed on a base structure, the second conductive line being located between and spaced apart from the first conductive line and the third conductive line; a conductive via formed on the second conductive line opposite to the base structure; two lower air gaps, each of which is located between the second conductive line and a respective one of the first conductive line and the third conductive line; a dielectric layer formed over the first conductive line, the second conductive line, the third conductive line and the two lower air gaps so that the conductive via is located in the dielectric layer; a first protection layer disposed to entirely separate the dielectric layer from the first conductive line, the second conductive line, the third conductive line, the conductive via and the two lower air gaps, the first protection layer including a material different from a material of the dielectric layer; two upper air gaps formed in the dielectric layer so that the two upper air gaps are located at two opposite sides of the conductive via; and a second protection layer formed over the dielectric layer and the two upper air gaps.

In accordance with some embodiments of the present disclosure, the two upper air gaps are respectively located directly above the two lower air gaps.

In accordance with some embodiments of the present disclosure, the second conductive line has two elongated parts and a connected part that is connected to the conductive via and is between the two elongated parts, and the two upper air gaps are formed directly above the two elongated parts of the second conductive line, respectively.

In accordance with some embodiments of the present disclosure, the first protection layer includes a porous dielectric film and an aluminum-based dielectric film.

In accordance with some embodiments of the present disclosure, a method for manufacturing an interconnect structure includes: forming a first conductive line, a second conductive line, and a third conductive line on a base structure, the second conductive line being located between and spaced apart from the first conductive line and the third conductive line; forming two lower air gaps each of which is located between the second conductive line and a respective one of the first conductive line and the third conductive line; forming a dielectric layer over the first conductive line, the second conductive line, the third conductive line and the two lower air gaps; forming a first protection layer to entirely separate the dielectric layer from the first conductive line, the second conductive line, the third conductive line and the two lower air gaps, the first protection layer including a material different from a material of the dielectric layer; forming two upper air gaps in the dielectric layer so that the two air gaps are located at two opposite sides of the conductive via; and forming a second protection layer over the dielectric layer and the two upper air gaps.

In accordance with some embodiments of the present disclosure, the two upper air gaps are respectively located directly above the two lower air gaps.

In accordance with some embodiments of the present disclosure, the second conductive line has two elongated parts and a connected part that is connected to the conductive via and is between the two elongated parts, and the two upper air gaps are formed directly above the two elongated parts of the second conductive line, respectively.

In accordance with some embodiments of the present disclosure, the first protection layer includes a porous dielectric film and an aluminum-based dielectric film.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing an interconnect structure, comprising:
forming a first conductive line, a second conductive line, and a third conductive line on a base structure, the second conductive line being located between and spaced apart from the first conductive line and the third conductive line;
forming a conductive via on the second conductive line opposite to the base structure;
forming two lower air gaps each of which is located between the second conductive line and a respective one of the first conductive line and the third conductive line;
forming a dielectric layer so that the conductive via is located in the dielectric layer; and
forming two upper air gaps in the dielectric layer so that the two upper air gaps are located at two opposite sides of the conductive via.

2. The method as claimed in claim 1, wherein the first conductive line, the second conductive line, the third conductive line and the conductive via are formed by:
forming a first conductive feature, a second conductive feature and a third conductive feature on the base structure, the first conductive feature, the second conductive feature, and the third conductive feature being spaced apart from each other;
forming a patterning mask which covers a portion of the second conductive feature;
performing a patterning process to pattern the first conductive feature, the second conductive feature, and the third conductive feature through the patterning mask so that the first conductive feature is formed into the first conductive line, the second conductive feature is formed into the second conductive line and the conductive via, and the third conductive feature is formed into the third conductive line; and
removing the patterning mask.

3. The method as claimed in claim 1, wherein forming the two lower air gaps includes:
forming a dielectric capping layer over the first conductive line, the second conductive line, the third conductive line, and the conductive via on the base structure;
forming a first sacrificial layer over the dielectric capping layer;
recessing the first sacrificial layer so that an upper portion of the dielectric capping layer, which is formed over the conductive via, is exposed from the recessed first sacrificial layer;
forming a first porous dielectric film over the recessed first sacrificial layer and the upper portion of the dielectric capping layer; and
after forming the first porous dielectric film, removing the recessed first sacrificial layer.

4. The method as claimed in claim 3, wherein an upper surface of the recessed first sacrificial layer is at a level lower than a level of an upper surface of each of the first conductive line, the second conductive line and the third conductive line.

5. The method as claimed in claim 3, wherein the first porous dielectric film includes silicon oxide, silicon oxycarbide, silicon oxynitride, silicon carbonitride or combinations thereof, and has a thickness ranging from 2 Å to 100 Å.

6. The method as claimed in claim 3, further comprising:
forming an aluminum-based dielectric film over the first porous dielectric film.

7. The method as claimed in claim 6, wherein the aluminum-based dielectric film is formed after removing the recessed first sacrificial layer.

8. The method as claimed in claim 6, wherein the aluminum-based dielectric film includes aluminum oxide, aluminum nitride, aluminum oxycarbide, or combinations thereof, and has a thickness ranging from 10 Å to 30 Å.

9. The method as claimed in claim 1, wherein after forming the dielectric layer, an upper surface of the conductive via is exposed from the dielectric layer.

10. The method as claimed in claim 9, wherein forming the two upper air gaps includes:
forming two recesses in the dielectric layer so that the two recesses are located at the two opposite sides of the conductive via;
forming a second sacrificial layer over the dielectric layer and the conductive via so as to fill the two recesses;
recessing the second sacrificial layer so that an upper surface of the recessed second sacrificial layer is at a level lower than a level of the upper surface of the conductive via;
forming a second porous dielectric film over the recessed second sacrificial layer and the conductive via; and
after forming the second porous dielectric film, removing the recessed second sacrificial layer.

11. A method for manufacturing an interconnect structure, comprising:
forming a first conductive line, a second conductive line, and a third conductive line on a base structure, each of the first conductive line, the second conductive line and the third conductive line being elongated in a lengthwise direction, the second conductive line being located between and spaced apart from the first conductive line and the third conductive line in a transverse direction that is transverse to the lengthwise direction;
forming a conductive via on the second conductive line opposite to the base structure in an upright direction transverse to both the lengthwise direction and the transverse direction;
forming two first air gaps, each of which is located between the second conductive line and a respective one of the first conductive line and the third conductive line;
forming a dielectric layer so that the conductive via is located in the dielectric layer;
forming two second air gaps in the dielectric layer so that the two second air gaps are located at two opposite sides of the conductive via in the transverse direction; and
forming two third air gaps in the dielectric layer so that the two third air gaps are located at another two opposite sides of the conductive via in the lengthwise direction.

12. The method as claimed in claim 11, wherein a projection of each of the two second air gaps on the base structure partially overlaps a projection of a respective one of the two first air gaps on the base structure.

13. The method as claimed in claim 11, wherein a projection of each of the two second air gaps on the base structure partially overlaps a projection of an adjacent corresponding one of the first conductive line and the third conductive line on the base structure.

14. The method as claimed in claim 11, wherein:
the second conductive line has two elongated parts and a connected part that is connected to the conductive via and is between the two elongated parts; and
the two third air gaps are formed directly above the two elongated parts of the second conductive line, respectively.

15. The method as claimed in claim 11, wherein each of the two first air gaps has a first length in the lengthwise direction, each of the two second air gaps has a second length in the lengthwise direction, and the first length is equal to the second length.

16. The method as claimed in claim 15, wherein each of the first conductive line, the second conductive line and the third conductive line has a length in the lengthwise direction, which is equal to each of the first length and the second length.

17. An interconnect structure, comprising:
a first conductive line, a second conductive line and a third conductive line, which are formed on a base structure, the second conductive line being located between and spaced apart from the first conductive line and the third conductive line;
a conductive via formed on the second conductive line opposite to the base structure;
two lower air gaps each of which is located between the second conductive line and a respective one of the first conductive line and the third conductive line;
a dielectric layer formed over the first conductive line, the second conductive line, the third conductive line and the two lower air gaps so that the conductive via is located in the dielectric layer;
a first protection layer disposed to entirely separate the dielectric layer from the first conductive line, the second conductive line, the third conductive line, the conductive via and the two lower air gaps, the first protection layer including a material different from a material of the dielectric layer;
two upper air gaps formed in the dielectric layer so that the two upper air gaps are located at two opposite sides of the conductive via; and
a second protection layer formed over the dielectric layer and the two upper air gaps.

18. The interconnect structure as claimed in claim 17, wherein the two upper air gaps are respectively located directly above the two lower air gaps.

19. The interconnect structure as claimed in claim 17, wherein:
the second conductive line has two elongated parts and a connected part that is connected to the conductive via and is between the two elongated parts; and
the two upper air gaps are formed directly above the two elongated parts of the second conductive line, respectively.

20. The interconnect structure as claimed in claim 17, wherein the first protection layer includes a porous dielectric film and an aluminum-based dielectric film.
